(19) United States
(12) Patent Application Publication
(10) Pub. No.: US 2026/0020238 A1
(43) Pub. Date: Jan. 15, 2026

(54) TECHNIQUES TO FORM BRIDGES BETWEEN BLOCKS OF MEMORY CELLS

(71) Applicant: Micron Technology, Inc., Boise, ID (US)

(72) Inventors: Sidhartha Gupta, Boise, ID (US); Richard J. Hill, Boise, ID (US); Matthew J. King, Boise, ID (US)

(21) Appl. No.: 19/264,300

(22) Filed: Jul. 9, 2025

Related U.S. Application Data
(60) Provisional application No. 63/671,528, filed on Jul. 15, 2024.

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

Methods, systems, and devices for techniques to form bridges between blocks of memory cells are described. A memory system may include a partial set of oxide bridges extending across a slot region between blocks of memory cells. For example, blocks of a memory system may include alternating layers of an oxide material and a conductive material. The blocks may be separated by a slot region. A first subset of the layers of oxide material may extend across the slot region to form oxide bridges, which may provide structural stability to the memory system. A second subset of the oxide layers, along with the conductive layers, may not extend across the slot region, which may support forming a trench during a manufacturing process of the memory system. Such a trench may provide an access point to the stack of layers to remove nitride material and deposit the conductive material.

### CROSS REFERENCE

The present application for Patent claims priority to U.S. Patent Application No. 63/671,528 by Gupta et al., entitled “TECHNIQUES TO FORM BRIDGES BETWEEN BLOCKS OF MEMORY CELLS,” filed Jul. 15, 2024, which is assigned to the assignee hereof, and which is expressly incorporated by reference in its entirety herein.

### TECHNICAL FIELD

The following relates to one or more systems for memory, including techniques to form bridges between blocks of memory cells.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports techniques to form bridges between blocks of memory cells in accordance with examples as disclosed herein.

FIG. 2 shows an example of a memory architecture that supports techniques to form bridges between blocks of memory cells in accordance with examples as disclosed herein.

FIGS. 3A through 5 show examples of layouts that support techniques to form bridges between blocks of memory cells in accordance with examples as disclosed herein.

FIGS. 6 and 7 show flowcharts illustrating methods that support techniques to form bridges between blocks of memory cells in accordance with examples as disclosed herein.

### DETAILED DESCRIPTION

Some memory devices, such as 3D memory systems, may include an arrangement of blocks of memory cells. In such systems, adjacent blocks of memory cells may be separated by slot regions that may provide isolation (e.g., electrical isolation) between the adjacent blocks. Manufacturing processes used to form such systems may include forming a stack of alternating layers of a nitride material and an oxide material, and forming a set of cavities through the stack of layers in the slot region. Such cavities may allow for metal depositions, such as replacement gate (RG) processes to replace layers of nitride with a conductive material and thus form a stack of word lines. In some cases, a trench may be formed by expanding the cavities (removing portions of the oxide material and the nitride material exposed by the cavities) to merge the set of cavities. However, such a trench may introduce manufacturing difficulties, such as block bending between blocks of memory cells. Alternatively, portions of the nitride material exposed by the cavities may be selectively removed, and the remaining oxide material may form a set of bridges that extend across the slot region. Such an approach may improve structural stability, but may reduce the quality of or increase complexity of the metal deposition process.

As described herein, a memory system may include a partial set of oxide bridges extending across a slot region between blocks of memory cells. For example, blocks of memory cells of a memory system may include alternating layers of an oxide material and a conductive material. The blocks of memory cells may be separated by a slot region. A first subset of the layers of oxide material may extend across the slot region to form oxide bridges, which may provide structural stability to the memory system. A second subset of the oxide layers, along with the conductive layers, may not extend across the slot region, which may support forming a trench (e.g., below the oxide bridges) during a manufacturing process of the memory system. Such a trench may support improved metallization processes, for example by providing an access point to the stack of layers to remove nitride material and deposit the conductive material. Such a manufacturing process may therefore improve metal deposition quality and improve block-to-block separation of the memory system.

In addition to applicability in memory systems as described herein, techniques to form bridges between blocks of memory cells may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving manufacturing efficiency and reliability, which may enable an increased density of memory cells in 3D memory systems, among other benefits.

Features of the disclosure are illustrated and described in the context of systems, devices, and circuits. Features of the disclosure are further illustrated and described in the context of layouts and flowcharts.

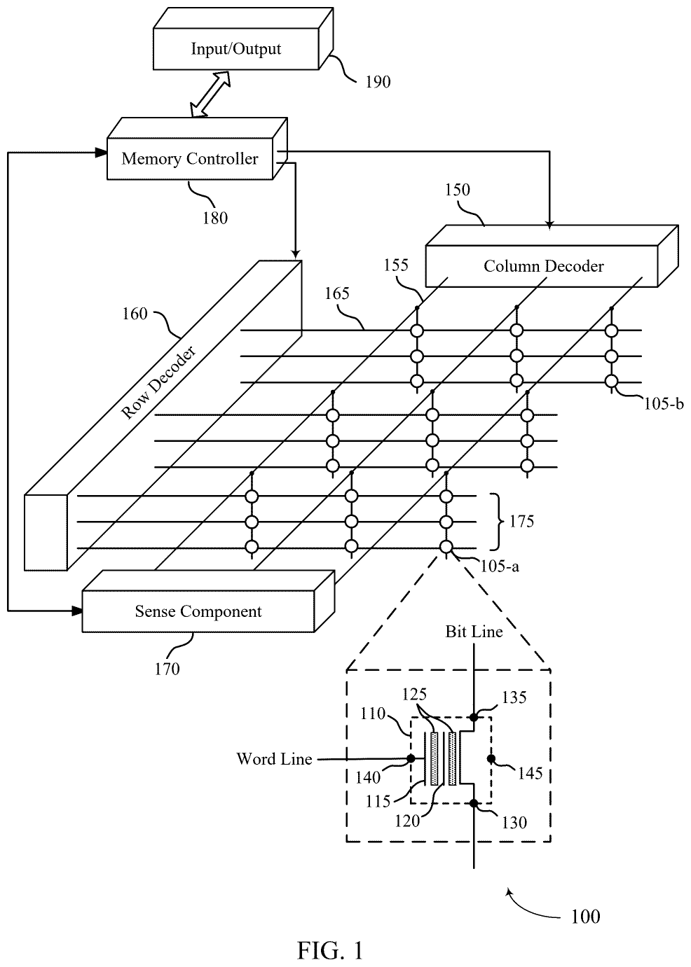

FIG. 1 shows an example of a memory device 100 that supports techniques to form bridges between blocks of memory cells in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

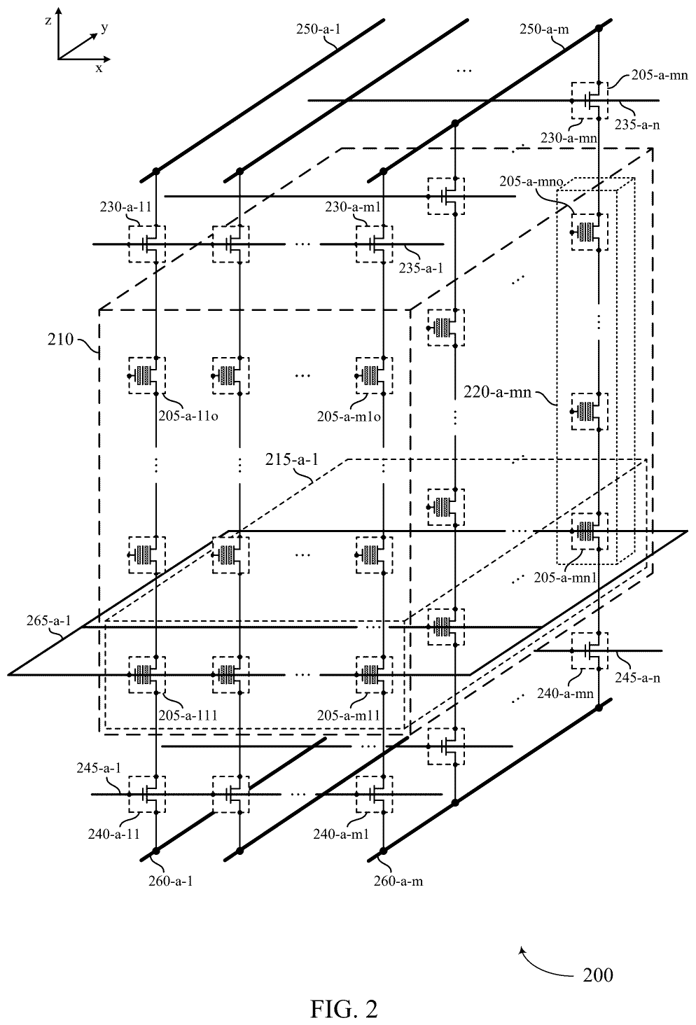

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

In some examples, a memory device 100 may include a partial set of oxide bridges extending across a slot region between blocks of memory cells 105. For example, blocks of memory cells 105 of a memory device 100 may include alternating layers of an oxide material and a conductive material. The blocks of memory cells 105 may be separated by a slot region. A first subset of the layers of oxide material may extend across the slot region to form oxide bridges, which may provide structural stability to the memory device 100. A second subset of the oxide layers, along with the conductive layers, may not extend across the slot region, which may support forming a trench (e.g., below the oxide bridges) during a manufacturing process of the memory device 100. Such a trench may support improved metallization processes, for example by providing an access point to the stack of layers to remove nitride material and deposit the conductive material. Such a manufacturing process may therefore improve metal deposition quality and improve block-to-block separation of the memory device 100.

FIG. 2 shows an example of a memory architecture 200 that supports techniques to form bridges between blocks of memory cells in accordance with examples as disclosed herein. The memory architecture 200 may be an example of a portion of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with the same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

In some examples, a memory system may include a partial set of oxide bridges extending across a slot region between blocks 210 of memory cells 205. For example, blocks 210 of a memory system may include alternating layers of an oxide material and a conductive material. The blocks 210 may be separated by a slot region. A first subset of the layers of oxide material may extend across the slot region to form oxide bridges, which may provide structural stability to the memory system. A second subset of the oxide layers, along with the conductive layers, may not extend across the slot region, which may support forming a trench (e.g., below the oxide bridges) during a manufacturing process of the memory system. Such a trench may support improved metallization processes, for example by providing an access point to the stack of layers to remove nitride material and deposit the conductive material. Such a manufacturing process may therefore improve metal deposition quality and improve block-to-block separation of the memory system.

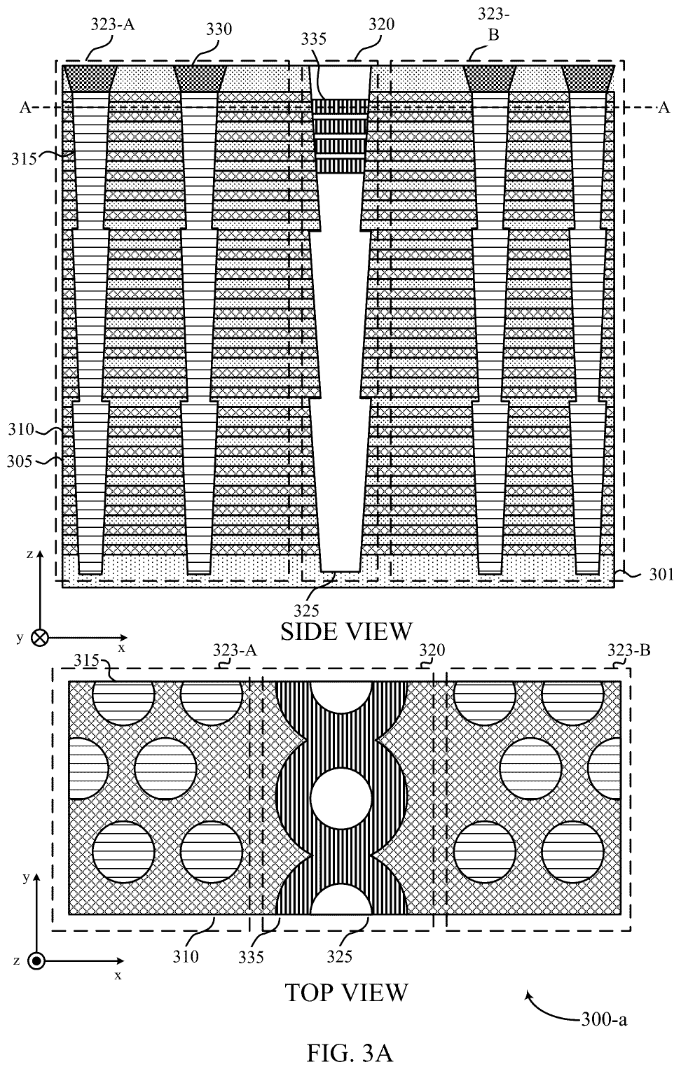

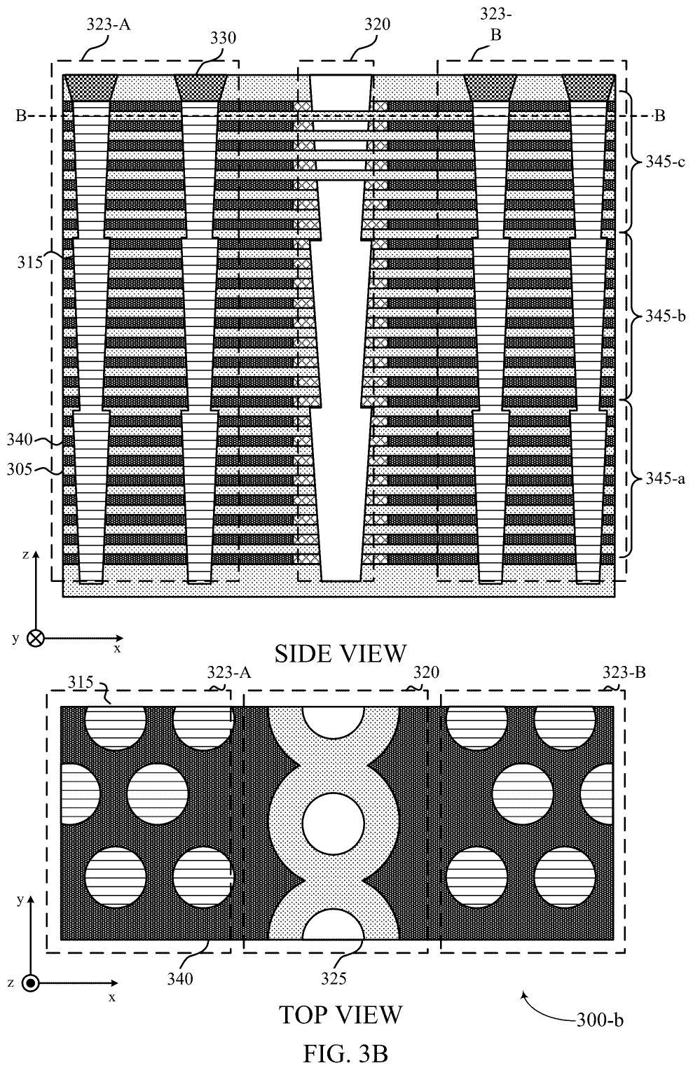

FIGS. 3A and 3B show examples of a layout 300-a and a layout 300-b that supports techniques to form bridges between blocks of memory cells in accordance with examples as disclosed herein. For example, FIGS. 3A and 3B may illustrate aspects (e.g., resulting structures) of a sequence of operations for fabricating aspects of the layouts 300, which may be a portion of a memory device (e.g., a portion of a memory device 100, a portion of a memory architecture 200, a portion of a memory die). Each view of the figures may be described with reference to an x-direction, a y-direction, and a z-direction, as illustrated, which may correspond to the respective directions described with reference to the memory architecture 200. Some of the provided figures include section views that illustrate example cross-sections of the layouts 300, respectively. For example, in FIGS. 3A and 3B a view “SIDE VIEW” may be associated with a cross-section in an xz-plane through a portion of the layout 300-a and 300-b, respectively, and a view “TOP VIEW” may be associated with a cross-section in an yz-plane through a portion of the layout 300-a and 300-b, respectively. Although the layouts 300 illustrate examples of certain relative dimensions and quantities of various features, aspects of the layouts 300 may be implemented with other relative dimensions or quantities of such features in accordance with examples as disclosed herein.

Operations illustrated in and described with reference to FIGS. 3A and 3B may be performed by a manufacturing system, such as a semiconductor fabrication system configured to perform additive operations for forming layers or structures of materials, subtractive operations for removing portions of materials, or other supporting operations such as masking, patterning, photolithography, or aligning, among other operations that support the described techniques. Additive operations may include deposition, doping, or bonding, while subtractive operations may include etching (e.g., dry etch, wet etch), trenching, planarizing, or polishing. In some examples, operations performed by such a manufacturing system may be supported by a process controller or its components as described herein.

The set of manufacturing operations may include forming (e.g., depositing) a stack of layers over a substrate 301. The substrate 301 may be a semiconductor wafer or other substrate over which the stack of layers is deposited. The stack of layers may include layers of a first material 305 and a second material 310 that alternate along the z-direction (e.g., in accordance with alternating material deposition operations). The first material 305 may include a dielectric material such as an oxide (e.g., silicon dioxide or another tier oxide), and may provide electrical isolation between levels of the layout 300-a. In some examples, the second material 310 may be a dielectric material, such as a nitride (e.g., silicon nitride or another tier nitride), and the layers of the second material 310 may be sacrificial layers. That is, the second material 310 may be subsequently removed (e.g., exhumed, etched) and replaced with one or more other materials that form aspects of the memory device.

In some cases, the stack of layers may be formed in direct contact with the substrate 301, or the layout 300-a may include other materials or components between the stack of layers and the substrate 301, such as interconnection or routing circuitry (e.g., access lines, sense lines, gate lines), control circuitry (e.g., transistors, aspects of a local memory controller, decoders, multiplexers, and the like), or another stack of layers (e.g., another stack of layers processed in accordance with examples as disclosed herein), which may include various conductor, semiconductor, or dielectric materials between the stack of layers and the substrate 301. In some examples, the substrate 301 itself may include such interconnection or routing circuitry (e.g., based on doping various portions of the substrate 301).

The set of manufacturing operations may include operations that support forming sets of cavities in accordance with examples as disclosed herein. For example, the set of manufacturing operations may include forming a set of first cavities and a set of second cavities 325 through the stack of layers (e.g., by removing portions of the first material 305 and the second material 310 along the z-direction to the substrate 301 or to an intervening material between the stack of layers and the substrate 301). In some examples, forming the set of first cavities and the set of second cavities may be performed as part of a same manufacturing step (e.g., at least partially in parallel).

The set of second cavities 325 may be formed in a slot region 320 of the layout 300. The slot region 320 may act as a barrier between adjacent blocks of memory cells. For example, during subsequent manufacturing operations, a first block of memory cells may be formed in the region 323-a, and a second block of memory cells may be formed in the region 323-b. The slot region 320 may be positioned between the region 323-a and the region 323-b and may insulate memory cells and related access circuitry formed in the region 323-a from memory cells and related access circuitry formed in the region 323-b.

The set of manufacturing operations may include operations that support forming a sacrificial material in the set of first cavities and the set of second cavities 325 in accordance with examples as disclosed herein. For example, the set of manufacturing operations may include depositing a sacrificial material, such as dielectric material or a semiconductor (e.g., polysilicon), in both the set of first cavities and the set of second cavities 325 (e.g., filling the cavities). After forming the sacrificial material in the set of first cavities and the set of second cavities 325, the set of manufacturing operations may include removing the sacrificial material from the set of first cavities. For example, the set of manufacturing operations may include selectively exhuming the sacrificial material from the set of first cavities, while retaining (e.g., not removing) the sacrificial material in the set of second cavities 325. Such selective removal may be achieved using various means, such as masking the set of second cavities 325 and etching the sacrificial material from the set of first cavities using a wet etch selective to the sacrificial material.

The set of manufacturing operations may include operations that support forming memory cell material and pillars 315 in the exhumed set of first cavities. For example, the set of manufacturing operations may include forming a memory material, such as a chalcogenide material, in portions of the set of first cavities. In some examples, the memory material may be deposited in the recesses formed by removing portions of the second material 310. After depositing the memory material, the set of manufacturing operations may include forming the pillars 315. For example, the set manufacturing operations may include depositing a material in each first cavity of the set of first cavities to form pillars 315. In some examples, the material may be an example of a metallic material, such as tungsten (W), and may form the conductive portion of the pillars of the memory device. Additionally, or alternatively, the material may be an example of a semiconductor material. In some cases, the set of manufacturing operations may include forming a set of protective caps 330 (e.g., “plugs”) over the pillars 315. For example, after forming the pillars 315, the set of manufacturing operations may include depositing a material to cover upper surfaces of the pillars 315. After forming the pillars 315, the set of manufacturing operations may include removing the sacrificial material from the set of second cavities.

The set of manufacturing operations may include forming a protective film 335 on exposed portions of a subset of layers of the first material 305. For example, the set of manufacturing operations may include a material deposition process to form the protective film 335 to cover the exposed portions of the first material 305. In some cases, the material deposition process may be configured or designed to deposit the protective film 335 on a subset of the layers of the first material 305. For example, the material deposition process may deposit the protective film 335 on a quantity of upper layers of the stack of materials, without depositing the protective film 335 on layers of the first material 305 below the subset of layers. In some examples, the protective film 335 may include a material such as carbon, or another material that may protect the portions of the subset of layers of the first material 305 from one or more subsequent material removal processes. Although FIG. 3A illustrates the protective film 335 formed on four layers of the first material 305, such an implementation is explanatory, and one skilled in the art may recognize that other quantities of layers are possible.

The set of manufacturing operations may include merging the second cavities 325 of the set of second cavities 325 to form a trench. For example, the set of manufacturing operations may include performing a procedure to remove portions of the first material 305 and the second material 310 from the set of second cavities. The procedure may include a wet etch that is selective to the first material 305 and the second material 310. In some cases, performing the wet etch may be performed via the set of second cavities 325, such as by depositing an etchant into the set of second cavities 325. For example, the procedure may remove a second subset of layers of the first material 305, such as the exposed portions of the first material 305 within the set of second cavities 325 (e.g., the portions of the first material 305 within the set of second cavities not covered by the protective film 335, the portions of the first material 305 exclusive of the subset of layers of the first material 305), along with the second material 310 within the set of second cavities. Further, the procedure may retain (e.g., not remove, remove at a slower rate) other materials, such as the protective film 335. Accordingly, after the procedure, the protective film 335 and the covered portions of the subset of layers of the first material 305 may remain. In some cases, the set of manufacturing operations may include removing the protective film 335 from the subset of layers of the first material 305 after removing the second subset of layers of the first material 305, for example using procedure (e.g., etch) that is selective to removing the material of the protective film 335.

Removing the second subset of layers of the first material 305 and the second material 310 within the set of second cavities 325 may merge adjacent cavities 325. For example, the procedure may widen each second cavity, such that adjacent cavities 325 may overlap to form a continuous trench extending in the y-direction within the slot region 320. Accordingly, layers of the first material 305 and layers of the second material 310 may not extend across the slot region 320 (e.g., layers of the first material 305 and layers of the second material 310 may terminate at sidewalls of the trench). The remaining portions of the subset of layers of the first material 305 may extend across the slot region 320 to form a set of bridges (e.g., oxide bridges) between the region 323-a and the region 323-b. The set of bridges may provide mechanical stability to the layout 300-a and the layout 300-b, which may mitigate physical distortions or other defects, such as block bending. Additionally, because the trench may be relatively free of obstruction (e.g., due to the removal of the first material 305 and the second material 310 from the set of second cavities), subsequent processing steps to replace the second material 310 in the region 323-a and the region 323-b with a conductive material (e.g., a subsequent RG process) may be improved.

For example, FIG. 3B illustrates the layout 300 after performing a metallization process. The set of manufacturing operations may include replacing at least a portion of the second material 310 with a conductive material 340 to form a set of word lines 165 in the stack of materials (e.g., an RG process) to form the memory cells. For example, the set of manufacturing operations may include removing the second material 310 using a procedure (e.g., etching procedure) selective to the second material 310. In some cases, the procedure may be performed via the set of second cavities 325, such as by inserting an etchant into the set of second cavities 325 that is configured to remove the second material 310 and form a set of voids between layers of the first material 305. The set of manufacturing operations may further include forming the conductive material 340 in the set of voids (e.g., by depositing the conductive material 340 via the set of second cavities 325) to form the word lines 165. In some examples, after forming the set of word lines 165, the set of manufacturing operations may include fill the trench formed by the set of second cavities 325 with a material. Such a material may be a dielectric material, and may provide additional structural stability to the layout 300 while isolating the region 323-a from the region 323-b. In some cases, at least a subset of the set of manufacturing operations may be repeated for subsets of layers of the stack of layers. For example, multiple removal processes may be performed to form the set of first cavities and set of second cavities. As shown in FIG. 3B, the removal processes may be repeated for each of subsets of layers 345 (e.g., first subset of layers 345-a, second subset of layers 345-b, and third subset of layers 345-c).

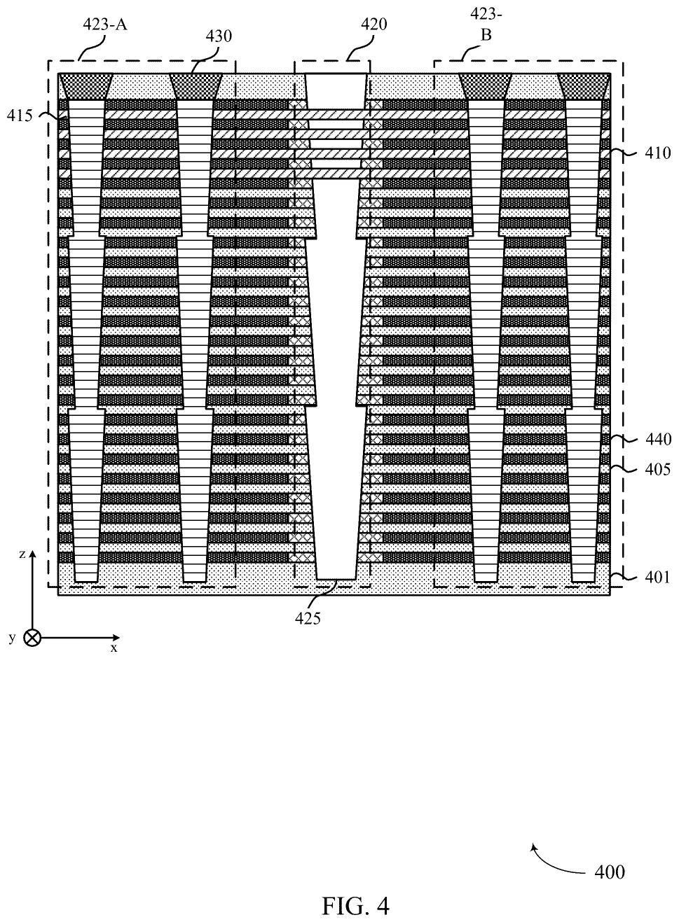

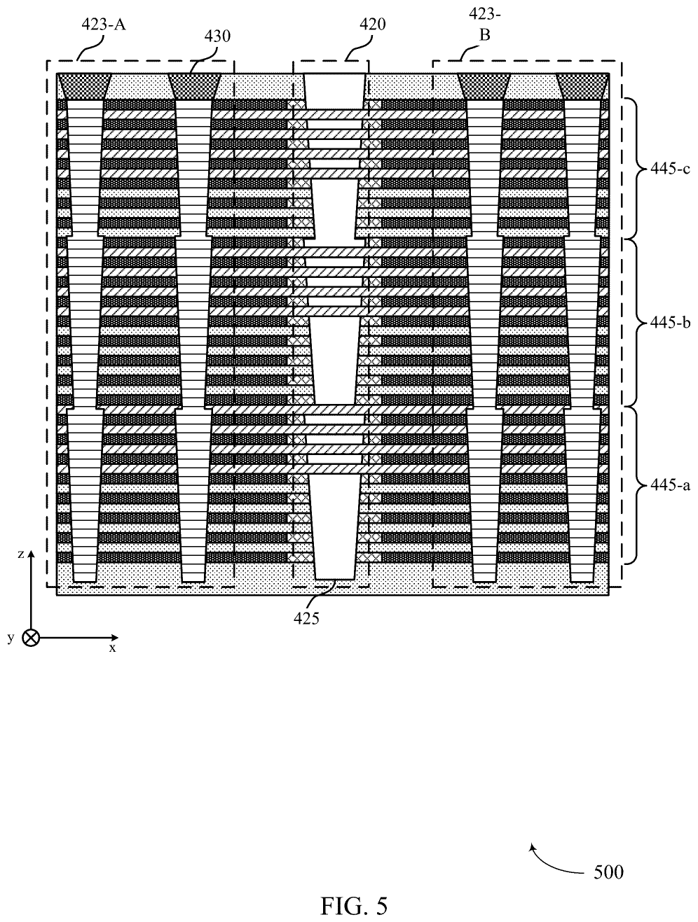

FIGS. 4 and 5 show examples of a layout 400 and a layout 500 that support techniques to form bridges between blocks of memory cells in accordance with examples as disclosed herein. For example, FIGS. 4 and 5 may illustrate aspects (e.g., resulting structures) of a sequence of operations for fabricating aspects of the layouts 400 and 500, which may be a portion of a memory device (e.g., a portion of a memory device 100, a portion of a memory architecture 200, a portion of a memory die). Each view of the figures may be described with reference to an x-direction, a y-direction, and a z-direction, as illustrated, which may correspond to the respective directions described with reference to the memory architecture 200. Although the layouts 400 and 500 illustrate examples of certain relative dimensions and quantities of various features, aspects of the layouts 400 and 500 may be implemented with other relative dimensions or quantities of such features in accordance with examples as disclosed herein.

Operations illustrated in and described with reference to FIGS. 4 and 5 may be performed by a manufacturing system, such as a semiconductor fabrication system configured to perform additive operations such as deposition, doping, or bonding, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

The set of manufacturing operations may include forming (e.g., depositing) a stack of layers over a substrate 401. The substrate 401 may be a semiconductor wafer or other substrate over which the stack of layers is deposited. The stack of layers may include layers of a first material 405 and a second material that alternate along the z-direction (e.g., in accordance with alternating material deposition operations). The first material 405 may include a dielectric material such as an oxide (e.g., silicon dioxide or another tier oxide), and may provide electrical isolation between levels of the layout 400. In some examples, the second material may be a dielectric material, such as a nitride (e.g., silicon nitride or another tier nitride), and the layers of the second material may be sacrificial layers. That is, the second material may be subsequently removed (e.g., exhumed, etched) and replaced with one or more other materials that form aspects of the memory device.

The set of manufacturing operations may include forming (e.g., depositing) an alternating stack of a quantity of layers of a third material 410 and the second material. For example, the set of manufacturing operations may include forming alternating layers of the third material 410 and the second material. In some examples, the third material 410 may be different than the first material 405. For example, the third material 410 may have a different selectively to a removal procedure (e.g., a different selectivity to an etchant of a wet etch), such that the removal procedure may be configured to remove all or a portion of the first material 405, without removing all of the third material 410. Additionally, or alternatively, the third material 410 may be formed by forming a layer of the first material 405 and modifying (e.g., doping, implanting) the layer of the first material 405 with a dopant material, such as carbon, to form the third material 410.

In some examples, prior to doping a layer of the first material 405 with a dopant to form the third material 410, the set of manufacturing operations may include masking the layer of the first material 405 at portions of the slot region 420. Such portions may be arranged along the y-direction, such that layer of the first material 405 includes alternating regions of masked and unmasked portions. Accordingly doping the layer of the first material 405 may form a layer having alternating portions of the third material 410 (e.g., corresponding to unmasked portions of the layer of the first material 405) and the first material 405 (e.g., corresponding to masked portions of the layer of the first material 405).

In some cases, the stack of layers may be formed in direct contact with the substrate 401, or the layout 400 may include other materials or components between the stack of layers and the substrate 401, such as interconnection or routing circuitry (e.g., access lines, sense lines, gate lines), control circuitry (e.g., transistors, aspects of a local memory controller, decoders, multiplexers, and the like), or another stack of layers (e.g., another stack of layers processed in accordance with examples as disclosed herein), which may include various conductor, semiconductor, or dielectric materials between the stack of layers and the substrate 401. In some examples, the substrate 401 itself may include such interconnection or routing circuitry (e.g., based on doping various portions of the substrate 401).

The set of manufacturing operations may include operations that support forming sets of cavities in accordance with examples as disclosed herein. For example, the set of manufacturing operations may include forming a set of first cavities and a set of second cavities 425 through the stack of layers (e.g., by removing portions of the first material 405 and the second material along the z-direction to the substrate 401 or to an intervening material between the stack of layers and the substrate 401). In some examples, forming the set of first cavities and the set of second cavities may be performed as part of a same manufacturing step (e.g., at least partially in parallel).

The set of second cavities 425 may be formed in a slot region 420 of the layout 400. The slot region 420 may act as a barrier between adjacent blocks of memory cells. For example, during subsequent manufacturing operations, a first block of memory cells may be formed in the region 423-a, and a second block of memory cells may be formed in the region 423-b. The slot region 420 may be positioned between the region 423-a and the region 423-b and may insulate memory cells and related access circuitry formed in the region 423-a from memory cells and related access circuitry formed in the region 423-b.

The set of manufacturing operations may include operations support forming a sacrificial material in the set of first cavities and the set of second cavities 425 in accordance with examples as disclosed herein. For example, the set of manufacturing operations may include depositing a sacrificial material, such as dielectric material or a semiconductor (e.g., polysilicon), in both the set of first cavities and the set of second cavities 425 (e.g., filling the cavities). After forming the sacrificial material in the set of first cavities and the set of second cavities 425, the set of manufacturing operations may include removing the sacrificial material from the set of first cavities. For example, the set of manufacturing operations may include selectively exhuming the sacrificial material from the set of first cavities, while retaining (e.g., not removing) the sacrificial material in the set of second cavities 425. Such selective removal may be achieved using various means, such as masking the set of second cavities 425 and etching the sacrificial material from the set of first cavities using a wet etch selective to the sacrificial material.

The set of manufacturing operations may include operations that support forming memory cell material and pillars 415 in the exhumed set of first cavities. For example, the set of manufacturing operations may include forming portions of a memory material, such as a chalcogenide material, in the set of first cavities. In some examples, the memory material may be formed (e.g., deposited) in the recesses formed by removing portions of the second material. After forming the portions of the memory material, the set of manufacturing operations may include forming the pillars 415. For example, the set manufacturing operations may include depositing a material in each first cavity of the set of first cavities to form pillars 415. In some examples, the material may be an example of a metallic material, such as tungsten (W), and may form the conductive portion of the pillars of the memory device. Additionally, or alternatively, the material may be an example of a semiconductor material. In some cases, the set of manufacturing operations may include forming a set of protective caps 430 (e.g., “plugs”) over the pillars 415. For example, after forming the pillars 415, the set of manufacturing operations may include depositing a material to cover upper surfaces of the pillars 415. After forming the pillars 415, the set of manufacturing operations may include removing the sacrificial material from the set of second cavities.

The set of manufacturing operations may include merging the second cavities 425 of the set of second cavities 425 to form a trench. For example, the set of manufacturing operations may include performing a procedure (e.g., an etching procedure) to remove portions of the first material 405 and the second material from the set of second cavities. The procedure may include a wet etch that is selective to the first material 405 and the second material. In some cases, performing the wet etch may be performed via the set of second cavities 425, such as by inserting an etchant into the set of second cavities 425. For example, the procedure may remove portions of a subset of layers of the first material 405, along with the second material within the set of second cavities. Further, the etching procedure may retain (e.g., not remove, remove at a slower rate) other materials, such as the third material 410. Accordingly, after the etching procedure, the third material 410 may remain.

Removing the subset of layers of the first material 405 and the second material within the set of second cavities 425 may merge adjacent cavities 425. For example, the procedure may widen each second cavity, such that adjacent cavities 425 may overlap to form a continuous trench extending in the y-direction within the slot region 420. Accordingly, layers of the first material 405 and layers of the second material may not extend across the slot region 420 (e.g., layers of the first material 405 and layers of the second material may terminate at sidewalls of the trench). The layers of the third material 410 may extend across the slot region 420 to form a set of bridges (e.g., oxide bridges) between the region 423-a and the region 423-b. In some examples, such as if portions of layers of the first material 405 are masked as part of forming the third material 410, the layouts 400 and 500 may include multiple sets of bridges arranged along the y-direction separated by regions without bridges, in accordance with the masked portions of layers of the first material 405.

The set of bridges may provide mechanical stability to the layouts 400 and 500, which may mitigate physical distortions or other defects, such as block bending. Additionally, because the trench may be relatively free of obstruction (e.g., due to the removal of the first material 405 and the second material from the set of second cavities), subsequent processing steps to replace the second material in the region 423-a and the region 423-b with a conductive material (e.g., a subsequent RG process) may be improved.

For example, the set of manufacturing operations may include replacing at least a portion of the second material with a conductive material 440 to form a set of word lines 165 in the stack of materials (e.g., an RG process) to form the memory cells. For example, the set of manufacturing operations may include removing the second material using an etching procedure selective to the second material. In some cases, the etching procedure may be performed via the set of second cavities 425, such as by depositing an etchant into the set of second cavities 425 configured to remove the second material and form a set of voids between layers of the first material 405. The set of manufacturing operations may further include forming the conductive material 440 in the set of voids (e.g., by depositing the conductive material 440 via the set of second cavities 425) to form the word lines 165. In some examples, after forming the set of word lines 165, the set of manufacturing operations may include depositing a material to fill the trench formed by the set of second cavities 325. Such a material may be a dielectric material, and may provide additional structural stability to the layouts 400 and 500 while isolating the region 423-a from the region 423-b.

In some cases, forming the layouts 400 and 500 may occur in multiple stages. For example, the set of manufacturing operations may include forming a deck 445-a, forming a deck 445-b above the deck 445-a, forming a deck 445-c above the deck 445-b, and so on. In such examples, the set of manufacturing operations may include forming a set of bridges in each deck 445, as illustrated in FIG. 5. Accordingly, the layout 500 may include multiple sets of decks 445 arranged along the z-direction at a periodicity (e.g., one set of bridges for each deck 445). Alternatively, the set of manufacturing operations may include forming a set of bridges at a single deck 445, or at a subset of the decks 445 of the layouts 400 and 500, as illustrated in FIG. 4.

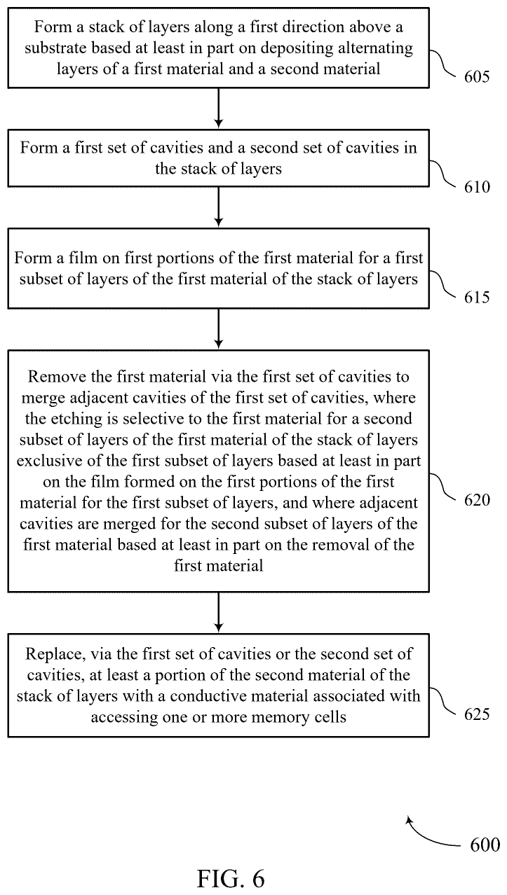

FIG. 6 shows a flowchart illustrating a method 600 that supports techniques to form bridges between blocks of memory cells in accordance with examples as disclosed herein. The operations of method 600 may be implemented by a manufacturing system or its components as described herein. For example, the operations of method 600 may be performed by a manufacturing system as described with reference to FIGS. 1 through 5. In some examples, a manufacturing system may execute a set of instructions to control the functional elements of the device to perform the described functions. Additionally, or alternatively, the manufacturing system may perform aspects of the described functions using special-purpose hardware.

At 605, the method may include forming a stack of layers along a first direction above a substrate based at least in part on forming alternating layers of a first material and a second material. Forming the alternating layers may include depositing the first material and the second material in alternating layers.

At 610, the method may include forming a first set of cavities and a second set of cavities in the stack of layers. Forming the first set of cavities and the second set of cavities may include etching the stack of layers using a dry etch.

At 615, the method may include forming a film on first portions of the first material for a first subset of layers of the first material of the stack of layers. Forming the film may including depositing the film (e.g., non-conformal film) on the first portions of the first material for the first subset of layers.

At 620, the method may include removing portions of the first material via the first set of cavities to merge adjacent cavities of the first set of cavities, where the removing is selective to the first material for a second subset of layers of the first material of the stack of layers exclusive of the first subset of layers based at least in part on the film formed on the first portions of the first material for the first subset of layers, and where adjacent cavities are merged for the second subset of layers of the first material based at least in part on the removal of the portions of the first material.

At 625, the method may include replacing, via the first set of cavities or the second set of cavities, at least a portion of the second material of the stack of layers with a conductive material associated with accessing one or more memory cells.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

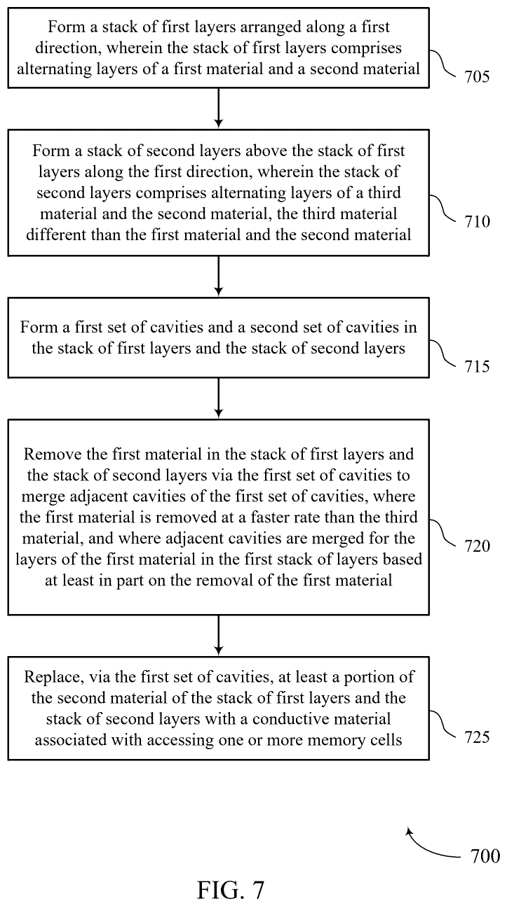

FIG. 7 shows a flowchart illustrating a method 700 that supports techniques to form bridges between blocks of memory cells in accordance with examples as disclosed herein. The operations of method 700 may be implemented by a manufacturing system or its components as described herein. For example, the operations of method 700 may be performed by a manufacturing system as described with reference to FIGS. 1 through 6. In some examples, a manufacturing system may execute a set of instructions to control the functional elements of the device to perform the described functions. Additionally, or alternatively, the manufacturing system may perform aspects of the described functions using special-purpose hardware.

At 705, the method may include forming a stack of first layers arranged along a first direction, where the stack of first layers may include alternating layers of a first material and a second material. Forming the stack of first layers may include depositing alternating layers of the first material and the second material.

At 710, the method may include forming a stack of second layers above the stack of first layers along the first direction, where the stack of second layers may include alternating layers of a third material and the second material. Forming the stack of second layers may include depositing alternating layers of a third material and the second material. The third material may be different than the first material and the second material.

At 715, the method may include forming a first set of cavities and a second set of cavities in the stack of first layers and the stack of second layers. The first and second sets of cavities may be formed using a dry etch.

At 720, the method may include removing portions of the first material in the stack of first layers and the stack of second layers via the first set of cavities to merge adjacent cavities of the first set of cavities, where the first material is removed at a faster rate than the third material, and where removing the portions of the first material merges adjacent cavities for the layers of the first material in the first stack of layers.

At 725, the method may include replacing, via the first set of cavities, at least a portion of the second material of the stack of first layers and the stack of second layers with a conductive material associated with accessing one or more memory cells.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for forming a stack of layers along a first direction above a substrate based at least in part on depositing alternating layers of a first material and a second material; forming a first set of cavities and a second set of cavities in the stack of layers; forming a film on first portions of the first material for a first subset of layers of the first material of the stack of layers; removing portions of the first material via the first set of cavities to merge adjacent cavities of the first set of cavities, where the removing is selective to the first material for a second subset of layers of the first material of the stack of layers exclusive of the first subset of layers based at least in part on the film formed on the first portions of the first material for the first subset of layers, and where adjacent cavities are merged for the second subset of layers of the first material based at least in part on the removal of the portions of the first material; and replacing, via the first set of cavities or the second set of cavities, at least a portion of the second material of the stack of layers with a conductive material associated with accessing one or more memory cells.

Aspect 2: The method, apparatus, or non-transitory computer-readable medium of aspect 1, further including operations, features, circuitry, logic, means, or instructions, or any combination thereof for filling each cavity of the first set of cavities and each cavity of the second set of cavities with a sacrificial material after forming the first set of cavities and the second set of cavities.

Aspect 3: The method, apparatus, or non-transitory computer-readable medium of aspect 2, further including operations, features, circuitry, logic, means, or instructions, or any combination thereof for exhuming the sacrificial material from the second set of cavities and filling each cavity of the second set of cavities with a third material associated with accessing the one or more memory cells, where the third material is a conductive material or a semiconductor material.

Aspect 4: The method, apparatus, or non-transitory computer-readable medium of aspect 3, further including operations, features, circuitry, logic, means, or instructions, or any combination thereof for forming a memory material in portions of at least a subset of layers of the second material of the stack of layers after exhuming the sacrificial material from the second set of cavities, where each cavity of the second set of cavities are filled with the third material after forming the memory material.

Aspect 5: The method, apparatus, or non-transitory computer-readable medium of any of aspects 3 through 4, further including operations, features, circuitry, logic, means, or instructions, or any combination thereof for exhuming the sacrificial material from the first set of cavities after exhuming the sacrificial material from the second set of cavities, where forming the film on the first portions is performed after exhuming the sacrificial material from the first set of cavities.

Aspect 6: The method, apparatus, or non-transitory computer-readable medium of any of aspects 1 through 5, where forming the first set of cavities and second set of cavities includes removing portions of the second material and second portions of the first material using a dry etch.

Aspect 7: The method, apparatus, or non-transitory computer-readable medium of any of aspects 1 through 6, where removing the first material via the first set of cavities includes removing third portions of the first material using a wet etch selective to the first material.

Aspect 8: The method, apparatus, or non-transitory computer-readable medium of any of aspects 1 through 7, where the film includes a carbon material.

Aspect 9: The method, apparatus, or non-transitory computer-readable medium of any of aspects 1 through 8, further including operations, features, circuitry, logic, means, or instructions, or any combination thereof for removing the film using an etch selective to the film.

Aspect 10: A method, apparatus, or non-transitory computer-readable medium including operations, features, circuitry, logic, means, or instructions, or any combination thereof for forming a stack of first layers arranged along a first direction, where the stack of first layers comprises alternating layers of a first material and a second material; forming a stack of second layers above the stack of first layers along the first direction, where the stack of second layers comprises alternating layers of a third material and the second material, the third material different than the first material and the second material; forming a first set of cavities and a second set of cavities in the stack of first layers and the stack of second layers; removing portions of the first material in the stack of first layers and the stack of second layers via the first set of cavities to merge adjacent cavities of the first set of cavities, where the etching removes the first material at a faster rate than the third material, and where removing the portions of the first material merges adjacent cavities for the layers of the first material in the first stack of layers; and replacing, via the first set of cavities, at least a portion of the second material of the stack of first layers and the stack of second layers with a conductive material associated with accessing one or more memory cells.

Aspect 11: The method, apparatus, or non-transitory computer-readable medium of aspect 10, where forming the stack of second layers includes operations, features, circuitry, logic, means, or instructions, or any combination thereof for forming one or more layers of the stack of second layers based at least in part on depositing the first material and doping the one or more layers of the stack of second layers with a fourth material, where doping the one or more layers forms the third material.

Aspect 12: The method, apparatus, or non-transitory computer-readable medium of aspect 11, where the fourth material includes carbon.

Aspect 13: The method, apparatus, or non-transitory computer-readable medium of any of aspects 11 through 12, further including operations, features, circuitry, logic, means, or instructions, or any combination thereof for masking portions of the one or more layers of the stack of second layers before doping the one or more layers, where the portions of the one or more layers are arranged along a second direction at a periodicity.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 14: An apparatus, including: a first block of memory cells including a first stack of layers, the first stack of layers including a first plurality of layers of a conductive material separated by a first plurality of layers of one or more dielectric materials, each memory cell of the first block of memory cells coupled between a respective layer of the conductive material and a respective pillar of a first plurality of pillars extending through the first stack of layers; a second block of memory cells including a second stack of layers, the second stack of layers including a second plurality of layers of the conductive material separated by a second plurality of layers of the one or more dielectric materials, each memory cell of the second block of memory cells coupled between a respective layer of the conductive material and a respective pillar of a second plurality of pillars extending through the second stack of layers; and a slot region separating the first stack of layers of the first block of memory cells from the second stack of layers of the second block of memory cells, where respective layers of the conductive material of the first plurality of layers are separated from corresponding layers of the conductive material of the second plurality of layers by the slot region, where a first subset of layers of the one or more dielectric materials of the first plurality of layers of the one or more dielectric materials are separated from corresponding layers of the one or more dielectric materials of the second plurality of layers by the slot region, and where a second subset of layers of the one or more dielectric materials of the first plurality of layers extend across the slot region to contact corresponding layers of the one or more dielectric materials of the second plurality of layers.

Aspect 15: The apparatus of aspect 14, where the one or more dielectric materials are a same dielectric material for each of the first subset of layers and the second subset of layers.

Aspect 16: The apparatus of any of aspects 14 through 15, where the first subset of layers of the one or more dielectric materials are a first dielectric material and the second subset of layers of the one or more dielectric materials are a second dielectric material different than the first dielectric material.

Aspect 17: The apparatus of aspect 16, where the first dielectric material is an oxide and the second dielectric material includes the oxide doped with a dopant material.

Aspect 18: The apparatus of aspect 17, where the dopant material is carbon.

Aspect 19: The apparatus of any of aspects 14 through 18, where the second subset of layers includes a plurality of groups of one or more layers, and each group of the second subset of layers is separated from other groups of the second subset of layers by one or more layers of the first subset of layers.

Aspect 20: The apparatus of aspect 19, where the first and second stacks of layers include a plurality of decks of layers, and the plurality of groups of one or more layers include one or more layers at corresponding locations in each deck of the plurality of decks of layers.

Aspect 21: The apparatus of any of aspects 14 through 20, where the second subset of layers are positioned above the first subset of layers relative to a substrate.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a first block of memory cells comprising a first stack of layers, the first stack of layers comprising a first plurality of layers of a conductive material separated by a first plurality of layers of one or more dielectric materials, each memory cell of the first block of memory cells coupled between a respective layer of the conductive material and a respective pillar of a first plurality of pillars extending through the first stack of layers;
a second block of memory cells comprising a second stack of layers, the second stack of layers comprising a second plurality of layers of the conductive material separated by a second plurality of layers of the one or more dielectric materials, each memory cell of the second block of memory cells coupled between a respective layer of the conductive material and a respective pillar of a second plurality of pillars extending through the second stack of layers; and
a slot region separating the first stack of layers of the first block of memory cells from the second stack of layers of the second block of memory cells, wherein respective layers of the conductive material of the first plurality of layers are separated from corresponding layers of the conductive material of the second plurality of layers by the slot region, wherein a first subset of layers of the one or more dielectric materials of the first plurality of layers of the one or more dielectric materials are separated from corresponding layers of the one or more dielectric materials of the second plurality of layers by the slot region, and wherein a second subset of layers of the one or more dielectric materials of the first plurality of layers extend across the slot region to contact corresponding layers of the one or more dielectric materials of the second plurality of layers.

2. The apparatus of claim 1, wherein the one or more dielectric materials are a same dielectric material for each of the first subset of layers and the second subset of layers.

3. The apparatus of claim 1, wherein the first subset of layers of the one or more dielectric materials are a first dielectric material and the second subset of layers of the one or more dielectric materials are a second dielectric material different than the first dielectric material.

4. The apparatus of claim 3, wherein the first dielectric material is an oxide and the second dielectric material comprises the oxide doped with a dopant material.

5. The apparatus of claim 4, wherein the dopant material is carbon.

6. The apparatus of claim 1, wherein:
the second subset of layers comprises a plurality of groups of one or more layers, and
each group of the second subset of layers is separated from other groups of the second subset of layers by one or more layers of the first subset of layers.

7. The apparatus of claim 6, wherein:
the first and second stacks of layers comprise a plurality of decks of layers, and
the plurality of groups of one or more layers comprise one or more layers at corresponding locations in each deck of the plurality of decks of layers.

8. The apparatus of claim 1, wherein the second subset of layers are positioned above the first subset of layers relative to a substrate.

9. A method, comprising:
forming a stack of layers along a first direction above a substrate based at least in part on forming alternating layers of a first material and a second material;
forming a first set of cavities and a second set of cavities in the stack of layers;
forming a film on first portions of the first material for a first subset of layers of the first material of the stack of layers;
removing portions of the first material via the first set of cavities to merge adjacent cavities of the first set of cavities, wherein the removing is selective to the first material for a second subset of layers of the first material of the stack of layers exclusive of the first subset of layers based at least in part on the film formed on the first portions of the first material for the first subset of layers, and wherein adjacent cavities are merged for the second subset of layers of the first material based at least in part on the removal of the portions of the first material; and
replacing, via the first set of cavities or the second set of cavities, at least a portion of the second material of the stack of layers with a conductive material associated with accessing one or more memory cells.

10. The method of claim 9, further comprising:
filling each cavity of the first set of cavities and each cavity of the second set of cavities with a sacrificial material after forming the first set of cavities and the second set of cavities.

11. The method of claim 10, further comprising:
exhuming the sacrificial material from the second set of cavities; and
filling each cavity of the second set of cavities with a third material associated with accessing the one or more memory cells, wherein the third material is a conductive material or a semiconductor material.

12. The method of claim 11, further comprising:
forming a memory material in portions of at least a subset of layers of the second material of the stack of layers after exhuming the sacrificial material from the second set of cavities, wherein each cavity of the second set of cavities are filled with the third material after forming the memory material.

13. The method of claim 11, further comprising:
exhuming the sacrificial material from the first set of cavities after exhuming the sacrificial material from the second set of cavities, wherein forming the film on the first portions is performed after exhuming the sacrificial material from the first set of cavities.

14. The method of claim 9, wherein forming the first set of cavities and second set of cavities comprises removing portions of the second material and second portions of the first material using a dry etch.

15. The method of claim 9, wherein removing the first material via the first set of cavities comprises removing third portions of the first material using a wet etch selective to the first material.

16. The method of claim 9, wherein the film comprises a carbon material.

17. The method of claim 9, further comprising:
removing the film using an etch selective to the film.

18. A method, comprising:
forming a stack of first layers arranged along a first direction, the stack of first layers comprising alternating layers of a first material and a second material;
forming a stack of second layers above the stack of first layers along the first direction, wherein the stack of second layers comprises alternating layers of a third material and the second material, the third material different than the first material and the second material;
forming a first set of cavities and a second set of cavities in the stack of first layers and the stack of second layers;
removing portions of the first material in the stack of first layers and the stack of second layers via the first set of cavities to merge adjacent cavities of the first set of cavities, wherein the first material is removed at a faster rate than the third material, and wherein removing the portions of the first material merges adjacent cavities for layers of the first material in the stack of first layers; and
replacing, via the first set of cavities, at least a portion of the second material of the stack of first layers and the stack of second layers with a conductive material associated with accessing one or more memory cells.

19. The method of claim 18, wherein forming the stack of second layers comprises:
forming one or more layers of the stack of second layers based at least in part on depositing the first material; and
doping the one or more layers of the stack of second layers with a fourth material, wherein doping the one or more layers forms the third material.

20. The method of claim 19, wherein the fourth material comprises carbon.

21. The method of claim 19, further comprising:
masking portions of the one or more layers of the stack of second layers before doping the one or more layers, wherein the portions of the one or more layers are arranged along a second direction at a periodicity.
